(19) United States
(12) Patent Application Publication
(10) Pub. No.: US 2013/0025662 A1
(43) Pub. Date: Jan. 31, 2013

(54) Water Soluble Dopant for Carbon Films

(71) Applicants: Ali Afzali-Ardakani, Ossining, NY (US); Ageeth Anke Bol, Yorktown Heights, NY (US); Bhupesh Chandra, Jersey City, NJ (US); George Stojan Tulevski, White Plains, NY (US)

(72) Inventors: Ali Afzali-Ardakani, Ossining, NY (US); Ageeth Anke Bol, Yorktown Heights, NY (US); Bhupesh Chandra, Jersey City, NJ (US); George Stojan Tulevski, White Plains, NY (US)

(73) Assignee: International Business Machines Corporation, Armonk, NY (US)

(21) Appl. No.: 13/189,909

(22) Filed: Jul. 25, 2011

(51) Int. Cl. H01B 1/24; H01L 31/0224; H01L 31/18; B82Y 30/00

(52) U.S. Cl. 136/256; 252/506; 438/98; 977/742; 977/734; 257/E31.126

(57) ABSTRACT

Techniques for reducing the resistivity of carbon nanotube and graphene materials are provided. In one aspect, a method of producing a doped carbon film having reduced resistivity is provided. The method includes the following steps. A carbon material selected from the group consisting of: a nanotube, graphene, fullerene and pentacene is provided. The carbon material and a dopant solution comprising an oxidized form of ruthenium bipyridyl are contacted, wherein the contacting is carried out under conditions sufficient to produce the doped carbon film having reduced resistivity.

### FIELD OF THE INVENTION

The present invention relates to electrical properties of carbon nanotube and graphene materials, and more particularly, to techniques for reducing the resistivity of carbon nanotube and graphene materials.

### BACKGROUND OF THE INVENTION

A conductive transparent electrode is an integral component of a photovoltaic cell. Indium tin oxide (ITO) is currently the most commonly used transparent electrode material. While ITO offers excellent optical and electrical properties, the fabrication of an ITO electrode involves costly vacuum deposition techniques. ITO (and other metal oxides) also suffer from being brittle and require high temperature processing steps not compatible with plastics, making them incompatible with flexible substrates. Further, with the increasing costs of mined metals, ITO is becoming a less economically viable solution for large scale photovoltaic cell production.

Carbon nanotubes are considered a leading candidate to replace ITO as the transparent electrode material in photovoltaic devices. As-grown carbon nanotubes consist of about one-third metallic and about two-thirds semiconducting carbon nanotubes. Thus, the minimum resistivity achievable with carbon nanotubes is limited, in part, by the presence of the semiconducting carbon nanotubes. In order to reduce the resistivity of a carbon nanotube film (without also reducing its transparency), carbon nanotube films are usually doped with acids (e.g., nitric acid) or some other oxidizing agent(s) (e.g., triethyloxonium hexachloroantimonate (AO)). However, in both cases there are particular shortcomings.

In the case of acid doping, the doped carbon nanotube films are not stable even at room temperature and, after several days, the extent of the doping is gradually diminished. In the case of AO type doping, the doping compound commonly used is only soluble in organic solvents, and specifically in chlorinated organic solvents which are not environmentally friendly for large scale use. Further, organic solvents are incompatible with traditional semiconductor photoresist processing and thus the use of organic solvents is a major roadblock for any process requiring photolithography.

Therefore, techniques for reducing the resistivity of carbon nanotube films without the use of organic solvents, wherein the films produced are stable and the transparency of the films is not diminished in the process would be desirable.

### SUMMARY OF THE INVENTION

The present invention provides techniques for reducing the resistivity of carbon nanotube and graphene materials. In one aspect of the invention, a method of producing a doped carbon film having reduced resistivity is provided. The method includes the following steps. A carbon material selected from the group consisting of: a nanotube, graphene, fullerene and pentacene is provided. The carbon material and a dopant solution comprising an oxidized form of ruthenium bipyridyl are contacted, wherein the contacting is carried out under conditions sufficient to produce the doped carbon film having reduced resistivity.

In another aspect of the invention, a method of fabricating a transparent electrode on a photovoltaic device from a carbon film is provided. The method includes the following steps. A carbon material selected from the group consisting of: a nanotube, graphene, fullerene and pentacene is provided. The carbon material and a dopant solution comprising an oxidized form of ruthenium bipyridyl are contacted, wherein the contacting is carried out under conditions sufficient to produce the doped carbon film having reduced resistivity on a surface of the photovoltaic device.

In yet another aspect of the invention, a photovoltaic device is provided. The photovoltaic device includes a bottom electrode; a first photoactive layer on the bottom electrode; a second photoactive layer on a side of the first photoactive layer opposite the bottom electrode; and a transparent electrode on a side of the second photoactive layer opposite the first photoactive layer, wherein the transparent electrode comprises a carbon film having carbon radical cations and a ruthenium bipyridyl dopant.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for reducing the resistivity of a carbon film according to an embodiment of the present invention;

FIG. 2 is a diagram illustrating another exemplary methodology for reducing the resistivity of a carbon film according to an embodiment of the present invention

FIG. 3 is an optical transmission spectrum from two single wall carbon nanotube films deposited over a glass substrate according to an embodiment of the present invention;

FIG. 4A is a cross-sectional diagram illustrating an exemplary photovoltaic device according to an embodiment of the present invention; and

FIG. 4B is a cross-sectional diagram illustrating a transparent electrode formed from a carbon nanotube film on the photovoltaic device of FIG. 4A according to an embodiment of the present invention.

### DETAILED DESCRIPTION OF PREFERRED EMBODIMENTS

Provided herein are techniques for reducing the resistivity of carbon films using an oxidized form of ruthenium bipyridyl. By way of example only, carbon films that may be doped using the present ruthenium bipyridyl-based doping techniques may be composed of carbon nanotube, graphene, fullerene and/or pentacene. Graphene is a one atom thick sheet of carbon atoms that are configured in a honeycomb structure. Carbon nanotubes, also composed entirely of carbon atoms, have a cylindrical shape and may be either single or multi walled. Fullerenes are a molecule composed of a precise number of carbon atoms (e.g., C60, C70, etc.) and have a spherical shape. Pentacene is an aromatic hydrocarbon containing five benzene rings, i.e.,

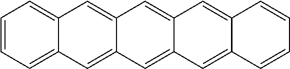 [SMILES: c1ccc2cc3cc4cc5ccccc5cc4cc3cc2c1]

Resistivity of the carbon films may be quantified as sheet resistance (Rs). For a carbon film of thickness t, sheet resistance (Rs) is related to bulk resistivity (ρ) by the relation Rs=ρ/t. In general, the present techniques involve doping the carbon molecules (i.e., carbon nantotubes, graphene, fullerenes and/or pentacene precursors) individually or as thin films with a ruthenium (Ru) compound derivative which is soluble in water.

Advantageously, the carbon films prepared in this manner do not exhibit diminished transparency after the doping. Thus, the films prepared according to the present techniques are well suited for applications requiring transparent films, such as transparent electrode structures in photovoltaic devices.

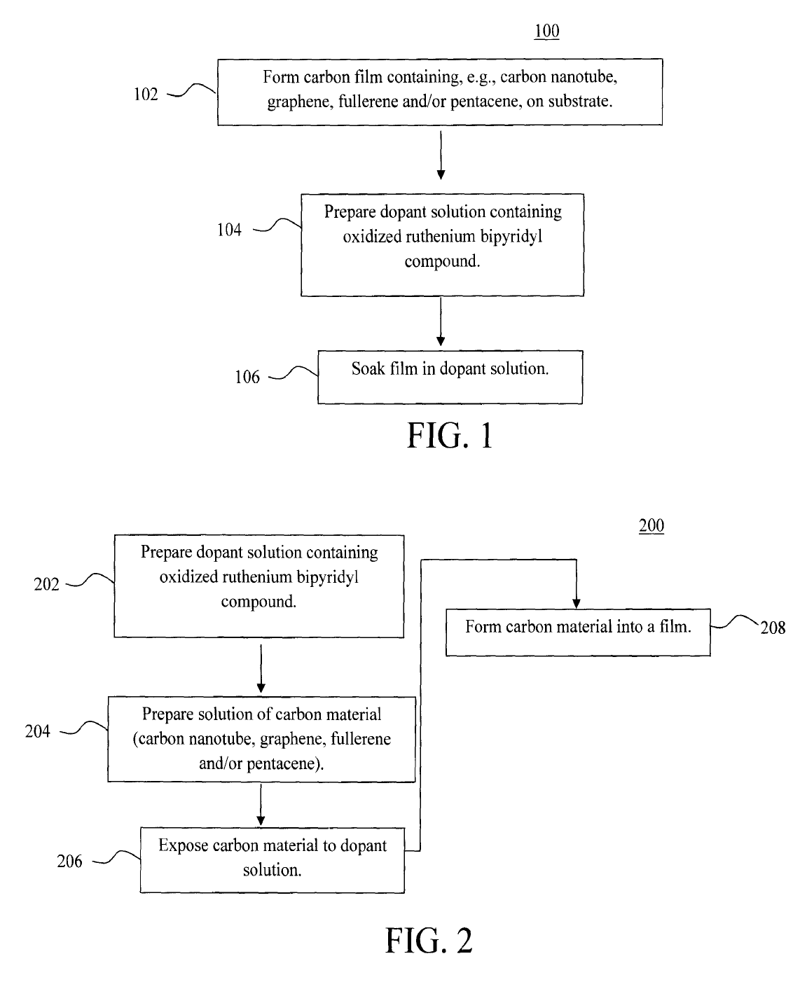

As highlighted above, the manner in which the doping of the carbon molecules is performed can vary. For example, doping of the carbon nanotube, graphene, fullerene and/or pentacene (pentacene can be formed from precursors in a solutions, see below) molecules can be carried out either before the molecules are formed into a film (i.e., the individual carbon nanotube, graphene, fullerene and/or pentacene precursor molecules are doped (see FIG. 1, described below)) or after the film is formed (see FIG. 2, described below).

FIG. 1 is a diagram illustrating an exemplary methodology 100 for reducing the resistivity of a carbon film wherein, i.e., carbon nanotubes, graphene, fullerene and/or pentacene, are formed into the film and the film itself is doped. Specifically, in step 102, the carbon film is formed (i.e., from carbon nanotube, graphene, fullerene and/or pentacene) on a substrate. Any suitable substrate may be employed and can vary depending on the particular application at hand. By way of example only, exemplary substrates include, but are not limited to, glass, silicon and plastic substrates. Any suitable film preparation technique may be used to form the carbon film. By way of example only, when the carbon film is formed from carbon nanotubes, the carbon nanotubes may be present in a solution (e.g., a solution of carbon nanotubes dispersed in a solvent such as water (with a surfactant) or an appropriate organic solvent(s)) and the carbon nanotubes may be deposited onto the substrate using chemical vapor deposition (CVD) growth, spray deposition and/or vacuum filtration to form the (carbon nanotube) film on the substrate. When the carbon film is formed from graphene, the graphene may be transferred to a suitable glass, semiconductor (e.g., silicon) or plastic substrate using an exfoliation technique to form the (graphene) film on the substrate. Alternatively, the graphene may be grown on the substrate. In that case, the substrate might be a silicon carbide substrate. Exfoliation and techniques for growing graphene from a silicon carbide substrate are known to those of skill in the art and thus are not described further herein. Further, the graphene may be present in a solution (e.g., a solution of graphene dispersed in a solvent such as N-Methyl-2-pyrrolidone (NMP)) and the graphene may be deposited onto the substrate using CVD growth, spray deposition and/or vacuum filtration to form the (graphene) film on the substrate. Similarly, when the carbon film is formed from fullerene, the fullerene may be present in a solution (e.g., a solution of fullerene molecules dispersed in a solvent such as water (with a surfactant) or an appropriate organic solvent(s)) and the fullerene molecules may be deposited onto the substrate using CVD growth, spray deposition and/or vacuum filtration to form the (fullerene) film on the substrate. When the carbon film is formed from pentacene, a thin film(s) of pentacene can be formed by vacuum evaporation of pentacene at high temperatures (e.g., from about 100° C. to about 200° C.) under vacuum of from about 1×10⁻⁵ to about 1×10⁻⁷ atmosphere or by solution deposition of pentacene precursors followed by thermal conversion of the pentacene precursors to a pentacene film(s) on the substrate. See below.

In step 104, a ruthenium dopant solution is prepared. The dopant solution contains an oxidized form of ruthenium bipyridyl (i.e., a ruthenium (III) complex) in a solvent. According to an exemplary embodiment, the dopant solution is prepared using a commercially available bivalent ruthenium bipyridyl complex obtained, for example, from Sigma-Aldrich®, St. Louis, Mo. Suitable bivalent ruthenium bipyridyl complexes include, but are not limited to, cis-Bis(isothiocyanato)(2,2-′bipyridyl-4,4′-dicarboxylato)(4,4′-di-nonyl-2′-bipyridyl)ruthenium(II), cis-Bis(isothiocyanato)bis(2,2′-bipyridyl-4,4′-dicarboxylato)ruthenium(II), Tris(2,2′-bipyridyl-d8)ruthenium(II) hexafluorophosphate, Di-tetrabutylammonium cis-bis(isothiocyanato)bis(2,2′-bipyridyl-4,4′-dicarboxylato)ruthenium(II) and Tris(2,2′-bipyridyl)dichlororuthenium(II) hexahydrate.

The bivalent ruthenium bipyridyl complex is then oxidized to form a trivalent ruthenium bipyridyl complex, e.g., tri-bipyridyl ruthenium hexafluorophosphate (Ru(BPy)₃(PF₆)₃). Suitable trivalent ruthenium bipyridyl complexes include, but are not limited to, ruthenium tris(2,2′)bipyridyl. The trivalent ruthenium bipyridyl complex is then dissolved in water with a resulting concentration of from about 0.1 milligram per milliliter (mg/ml) to about 10 mg/ml. Alternatively, instead of water, an organic solvent may be employed in the same manner employing the same concentration. Suitable organic solvents include, but are not limited to, acetonitrile and/or dimethylformamide. Ru(BPy)₃(PF₆)₃ also has some limited solubility in water (about 1 mg/ml).

In step 106, the carbon film, formed in step 102 (i.e., from carbon nanotube, graphene, fullerene and/or pentacene), is contacted with the ruthenium dopant solution. According to an exemplary embodiment, the carbon film and substrate are soaked in the dopant solution for a duration of from about 15 seconds to about 30 minutes at a temperature of from about 25 degrees Celsius (° C.) to about 100° C. As highlighted above, the doping solution preferably has a concentration (of trivalent ruthenium bipyridyl in the solvent) of from about 0.1 mg/ml to about 10 mg/ml. After the soaking, the film/substrate are removed from the dopant solution and washed thoroughly with distilled water. In this process the carbon molecules in the film are doped by electron transfer process from the carbon atoms in the carbon nanotube, graphene, fullerene and/or pentacene molecules to the ruthenium compound to form carbon radical cations as depicted in the following equation.

Carbon molecule+n[Ru(bpy)₃]³⁺→Carbon molecule^{n(+•)}+n[Ru(byp)₃]²⁺

Films prepared in this manner were found to have a resistivity that is one third lower than that of untreated films.

As highlighted above, the present techniques can alternatively be used to dope the carbon molecules (i.e., carbon nanotube, graphene, fullerene and/or pentacene) prior to the carbon molecules being formed into a film (i.e., the carbon nanotube, graphene, fullerene and/or pentacene precursors can be doped in solution). This process is shown in FIG. 2. FIG. 2 is a diagram illustrating exemplary methodology 200 for reducing the resistivity of a carbon film wherein the carbon nanotubes, graphene, fullerene and/or pentacene that make up the film are doped in solution prior to being formed into the film.

In step 202, the present ruthenium dopant solution is prepared. The process for preparing the ruthenium dopant solution using a commercially available bivalent ruthenium bipyridyl complex was described in conjunction with the description of step 104 of FIG. 1, above. That description is incorporated by reference herein.

In step 204, a solution containing the constituent carbon materials (e.g., carbon nanotube, graphene, fullerene and/or pentacene precursor (see below) molecules) that will be used to form the film is prepared. By way of example only, a solution of carbon nanotubes can be prepared by dispersing powdered carbon nanotubes in a liquid medium such as water (with a surfactant), an appropriate organic solvent(s) such as dimethylformamide (DMF), NMP and/or dichloroethylene (DCE) or by functionalizing the carbon nanotubes with groups that aid in dispersion and then dispersing them in, e.g., an organic solvent. The carbon nanotubes can then be purified by high speed centrifugation, either with or without a step gradient. As highlighted above, a solution of graphene may be prepared by dispersing the graphene in a solvent such as N-Methyl-2-pyrrolidone (NMP).

Similarly, a fullerene solution can be prepared by dispersing the fullerene molecules in a liquid medium such as water (with a surfactant), an appropriate organic solvent(s) such as DMF, NMP and/or DCE. A solution of pentacene precursors can be prepared. Thermal conversion can later be used to convert the precursors to a pentacene film. Precursor solutions and techniques for converting the precursors to materials such as pentacene films are described, for example, in U.S. Pat. No. 7,429,552 B2 issued to Afzali-Ardakani et al., entitled “System and Method of Transfer Printing an Organic Semiconductor,” U.S. Pat. No. 7,176,484 B2 issued to Afzali-Ardakani et al., entitled “Use of an Energy Source to Convert Precursors into Patterned Semiconductors,” U.S. Pat. No. 6,963,080 B2 issued to Afzali-Ardakani et al., entitled “Thin Film Transistors Using Solution Processed Pentacene Precursor as Organic Semiconductor,” U.S. Pat. No. 6,918,982 B2 issued to Afzali-Ardakani et al., entitled “System and Method of Transfer Printing an Organic Semiconductor,” U.S. Pat. No. 5,721,299 issued to Angelopoulos et al., entitled “Electrically Conductive and Abrasion/Scratch Resistant Polymeric Materials, Method of Fabrication Thereof and Uses Thereof,” U.S. Pat. No. 7,125,989 B2 issued to Afzali-Ardakani et al., entitled “Hetero Diels-Alder Adducts of Pentacene as Soluble Precursors of Pentacene,” (hereinafter “U.S. Pat. No. 7,125,989”), U.S. Pat. No. 7,381,585 B2 issued to Afzali-Ardakani et al., entitled “System and Method of Transfer Printing an Organic Semiconductor,” and Afzali et al., “High-Performance, Solution-Processed Organic Thin Film Transistors From a Novel Pentacene Precursor,” J. Am. Chem. Soc. 124, 8812-8813 (2002), the contents of each of which are incorporated by reference herein.

By way of example only, U.S. Pat. No. 7,125,989 describes organic solvent-soluble Diels-Alder adducts of polycyclic aromatic compounds, such as, oligothiophene, perylene, benzo[ghi]perylene, coronene and polyacenes, with variety of dienophiles containing at least one heteroatom and in some cases two heteroatoms bonded to aromatic moiety, such as, thioxomalonates, azodicarboxylates, thialdehyde, acylnitroso and N-sulfinylamides. The Diels-Alder adducts are prepared by a simple, one step cycloaddition reaction of the polycyclic aromatic compounds, such as, pentacene, or other fused aromatic compounds, with heterodienophiles. The Diels-Alder adducts according to the present invention all form soluble adducts with pentacene and can be converted back to pentacene by retro-Diels-Alder reaction at moderate (60-250° C.) temperatures both in bulk, in solution or as thin-films. The adducts are soluble in a variety of common organic solvents including hydrocarbons, chlorinated hydrocarbons, ethers, esters and ketones.

In step 206, the constituent carbon (e.g., carbon nanotube, graphene, fullerene and/or pentacene precursor (e.g., Diels-Alder adducts)) material is contacted with the dopant solution. Namely, according to an exemplary embodiment, the ruthenium dopant solution (prepared in step 202) is mixed with the constituent carbon (e.g., carbon nanotube, graphene, fullerene and/or pentacene precursor) material solution. According to an exemplary embodiment, the ruthenium dopant solution is added directly to the carbon nanotube, graphene, fullerene and/or pentacene precursor solution and the combined solutions are stirred (to aid in the mixing) for a duration of from about 15 seconds to about 30 minutes at a temperature of from about 25° C. to about 100° C. By way of example only, the dopant solution concentration employed may be from about 0.01 millimolar (mM) to about 10 mM, mixed in volume ratio of from about 0.1 mM to about 10 mM to the carbon nanotube, graphene, fullerene and/or pentacene precursor solution (a concentration of from about 0.01 mg/ml to about 1 mg/ml).

In this manner, the dopant can thoroughly dope the constituent carbon materials in solution. Namely, this process of doping the carbon nanotube, graphene, fullerene and/or pentacene precursors in solution is highly advantageous because the dopant molecules can reach all surface areas of the carbon nanotube, graphene, fullerene and/or pentacene precursor molecules individually to completely dope the molecules. When in dry form (as films), the constituent carbon nanotube, graphene, fullerene and/or pentacene molecules cannot be completely doped since they exist as bundles. Thus, dopant molecules would have to diffuse inside the bundle to dope every molecule completely and the diffusion is limited by the size of the dopant molecule. Further, in the instance where the constituent carbon materials are dispersed in an aqueous solution (with surfactant), other water-insoluble dopants cannot be used in this approach.

In step 208, a film is formed from the constituent carbon (e.g., carbon nanotube, graphene, fullerene and/or pentacene precursor) materials on a given substrate. Any suitable substrate may be employed and can vary depending on the particular application at hand. Exemplary substrates include, but are not limited to, glass, silicon and plastic substrates. Any film preparation technique may be used to form the film from the given constituent solution. Exemplary film synthesis techniques include, but are not limited to, CVD growth, spray deposition and vacuum filtration. As highlighted above, solution deposition of pentacene precursors followed by thermal conversion of the pentacene precursors to pentacene can be used to form a pentacene film. These synthesis techniques are known to those of skill in the art and thus are not described further herein.

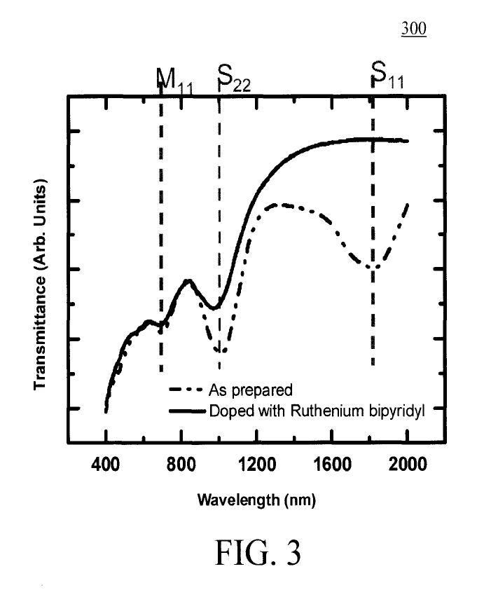

FIG. 3 is an optical transmission spectrum 300 from two single wall carbon nanotube films deposited over a glass substrate. In spectrum 300, wavelength (measured in nanometers (nm)) is plotted on the x-axis and transmittance (measured in arbitrary units (Arb. Units)) is plotted on the y-axis. The dashed curve shows the film, as prepared, with no dopant addition. The dip in transmission at three wavelength ranges (S11, S22 and M11) denotes light absorption due to carrier excitation. This is a unique signature of one-dimensional band structure of single wall carbon nanotubes.

After doping with the present ruthenium doping solution as described above (represented by the solid curve), the transmission dip at S11 is completely gone, whereas the dips at S22 and M11 have become weaker. This change in transmission is due to the p-type doping effect of the ruthenium dopant. The decrease in electron concentration (or increase in hole) due to the application of the dopant bleaches off the electron transition inside the single wall carbon nanotube samples. When a dopant takes out electrons from nanotubes, it dopes them with holes thereby decreasing the resistivity (holes are majority current carriers). Electrons and holes are similar in nanotubes. A p-type dopant such as ruthenium dopes the tubes with holes by depleting them with electrons. An n-type dopant dopes the tubes with electrons and depletes the hole population. In both cases, the resistivity of the tubes gets decreased as the carrier population is increased. Using the present doping techniques, the resistivity of a carbon nanotube film can be decreased by half (as compared to an undoped film).

Film transparency (usually quoted at 550 nm for transparent conductors, see FIG. 3) is not affected much after doping. However, if the transparency is averaged over the whole visible spectrum (which is the case for photovoltaic devices), the transparency is found to advantageously increase after implementation of the present doping techniques. This result is mainly due to the reduction in absorption peaks due to the doping, as shown in FIG. 3.

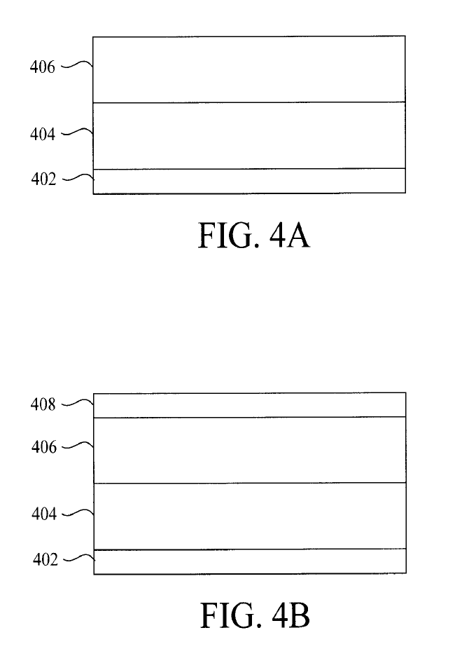

A carbon film may be employed as the transparent electrode material in photovoltaic devices. The present doping techniques can be used to reduce the resistivity of these materials. Further, advantageously, use of the present ruthenium dopant solution does not diminish (and in fact may increase, see above) the transparency of the carbon film, which is important when the carbon film is being used as a transparent electrode in a photovoltaic device. FIGS. 4A and 4B are diagrams illustrating an exemplary methodology for fabricating a transparent electrode on a photovoltaic device from a carbon film.

A generic photovoltaic device is shown in FIG. 4A. The photovoltaic device includes a bottom electrode 402, a first photoactive layer 404 (disposed on the bottom electrode) and a second photoactive layer 406 (disposed on a side of first photoactive layer 404 opposite bottom electrode 402). By way of example only, the first and second photoactive layers can be doped so as to have opposite polarities from one another, e.g., one is doped with a p-type dopant and the other is doped with an n-type dopant. In this example, a p-n junction would be formed between the two photoactive layers. Such a generic photovoltaic device would be apparent to one of skill in the art and thus is not described further herein. Further, as would be apparent to one of skill in the art, there are a multitude of different photovoltaic device configurations possible, and the configuration shown in FIG. 4A is provided merely to illustrate the present techniques for fabricating a transparent electrode on the photovoltaic device from a carbon nanotube film or a graphene sheet(s) having decreased resistivity.

As shown in FIG. 4B, a carbon film 408 which will serve as the transparent electrode is formed (disposed) on a surface of the photovoltaic device, i.e., on a surface of second photoactive layer 406 opposite first photoactive layer 404. In the examples provided, e.g., in conjunction with the description of FIGS. 1 and 2, above, the carbon films are formed on a substrate. As highlighted above, the given substrate can vary depending on the particular application at hand. In this case, the substrate is the photovoltaic device. Thus, in this example, the carbon film is formed from carbon nanotube, graphene, fullerene and/or pentacene molecules.

As described in detail above, the resistivity of the carbon film can be reduced by exposing the constituent carbon (e.g., carbon nanotube, graphene, fullerene and/or pentacene) materials of the film to a dopant solution containing an oxidized form of ruthenium bipyridyl (e.g., Ru(BPy)₃(PF₆)₃) in a solvent (e.g., water) either in solution (i.e., prior to forming the film) or as a film. The above-described techniques for doping the carbon nanotube, graphene, fullerene and/or pentacene precursor molecules in solution or after the constituent materials have been formed into a film are incorporated by reference herein. When the latter technique is used, the photovoltaic device with the carbon film formed thereon can be exposed to (e.g., soaked in) the dopant solution.

The carbon film 408 can be formed on the surface of the photovoltaic device in a number of different ways. Suitable film synthesis techniques were described above. The film synthesis technique may vary depending on the particular carbon material being employed and whether or not the constituent carbon materials have been doped in solution prior to the film deposition. By way of example only, when the constituent carbon (e.g., carbon nanotube, graphene, fullerene and/or pentacene precursor) materials have been doped in solution, then CVD growth, spray deposition or vacuum filtration may be used to form carbon film 408 from the given doped solution. As highlighted above, in the case of pentacene, solution deposition of the pentacene precursors followed by thermal conversion of the pentacene precursors to pentacene may be used to form carbon film 408 from the given doped precursor solution. CVD growth, spray deposition, vacuum filtration, and in the case of pentacene solution deposition of precursors/thermal conversion may also be used to deposit carbon nanotubes, graphene, fullerene and/or pentacene on the photovoltaic device so as to form film 408 (which can then be subsequently doped). Alternatively, as described above, when the film is composed of graphene, the graphene may also be formed using transfer (e.g., exfoliation) techniques.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method of producing a doped carbon film having reduced resistivity, the method comprising the steps of:
providing a carbon material selected from the group consisting of: a nanotube, graphene, fullerene and pentacene; and
contacting: (i) the carbon material and (ii) a dopant solution comprising an oxidized form of ruthenium bipyridyl, wherein the contacting is carried out under conditions sufficient to produce the doped carbon film having reduced resistivity.

2. The method of claim 1, wherein the conditions are selected from: temperature and duration.

3. The method of claim 2, wherein the duration is from about 15 seconds to about 30 minutes.

4. The method of claim 2, wherein the temperature is from about 25° C. to about 100° C.

5. The method of claim 1, wherein the carbon material is in a solution, the method further comprising the step of:
forming the carbon material into the film after the contacting step has been performed.

6. The method of claim 1, wherein the carbon material is in a form of a film.

7. The method of claim 1, further comprising the step of:
preparing the dopant solution by the steps of:
oxidizing a bivalent ruthenium bipyridyl complex to form the oxidized form of ruthenium bipyridyl; and
dissolving the oxidized form of ruthenium bipyridyl in a solvent.

8. The method of claim 7, wherein the bivalent ruthenium bipyridyl complex is selected from the group consisting of: cis-Bis(isothiocyanato)(2,2′-bipyridyl-4,4′-dicarboxylato)(4,4′-di-nonyl-2′-bipyridyl)ruthenium(II), cis-Bis(isothiocyanato)bis(2,2′-bipyridyl-4,4′-dicarboxylato)ruthenium(II), Tris(2,2′-bipyridyl-d8)ruthenium(II) hexafluorophosphate, Di-tetrabutylammonium cis-bis(isothiocyanato)bis(2,2′-bipyridyl-4,4′-dicarboxylato)ruthenium(II) and Tris(2,2′-bipyridyl)dichlororuthenium(II) hexahydrate.

9. The method of claim 7, wherein the solvent is water.

10. The method of claim 7, wherein a concentration of the oxidized form of ruthenium bipyridyl in the solvent is from about 0.1 mg/ml to about 10 mg/ml.

11. The method of claim 1, wherein the oxidized form of ruthenium bipyridyl is ruthenium tris(2,2′)bipyridyl.

12. A method of fabricating a transparent electrode on a photovoltaic device from a doped carbon film, comprising the steps of:
providing a carbon material selected from the group consisting of: a nanotube, graphene, fullerene and pentacene; and
contacting: (i) the carbon material and (ii) a dopant solution comprising an oxidized form of ruthenium bipyridyl, wherein the contacting is carried out under conditions sufficient to produce the doped carbon film having reduced resistivity on a surface of the photovoltaic device.

13. The method of claim 12, wherein the conditions are selected from: temperature and duration.

14. The method of claim 13, wherein the duration is from about 15 seconds to about 30 minutes.

15. The method of claim 13, wherein the temperature is from about 25° C. to about 100° C.

16. The method of claim 12, wherein the carbon material is in a solution, the method further comprising the step of:
forming the carbon material into the film on the surface of the photovoltaic device after the contacting step has been performed.

17. The method of claim 12, wherein the carbon material is in a form of a film.

18. The method of claim 12, further comprising the step of:
preparing the dopant solution by the steps of:
oxidizing a bivalent ruthenium bipyridyl complex to form the oxidized form of ruthenium bipyridyl; and
dissolving the oxidized form of ruthenium bipyridyl in a solvent.

19. The method of claim 18, wherein a concentration of the oxidized form of ruthenium bipyridyl in the solvent is from about 0.1 mg/ml to about 10 mg/ml.

20. A photovoltaic device, comprising:
a bottom electrode;
a first photoactive layer on the bottom electrode;
a second photoactive layer on a side of the first photoactive layer opposite the bottom electrode; and
a transparent electrode on a side of the second photoactive layer opposite the first photoactive layer, wherein the transparent electrode comprises a carbon film having carbon radical cations and a ruthenium bipyridyl dopant.
